(19) United States
(12) Patent Application Publication
(10) Pub. No.: US 2021/0017647 A1
(43) Pub. Date: Jan. 21, 2021

(54) LOCALIZED SURFACE COATING DEFECT PATCHING PROCESS

(71) Applicant: Robert Bosch GmbH, Stuttgart (DE)

(72) Inventors: Jonathan MAILOA, Cambridge, MA (US); Georgy SAMSONIDZE, San Francisco, CA (US); Mordechai KORNBLUTH, Brighton, MA (US); Soo KIM, Cambridge, MA (US); Boris KOZINSKY, Waban, MA (US); Jake CHRISTENSEN, Elk Grove, CA (US)

(21) Appl. No.: 16/515,203

(22) Filed: Jul. 18, 2019

(51) Int. Cl. C23C 16/455; G01N 21/62; G01N 21/88; C23C 16/04

(52) U.S. Cl. CPC C23C 16/45529; C23C 16/45551; G01N 2021/646; G01N 21/88; C23C 16/04; G01N 21/62

(57) ABSTRACT

A method of producing a coating. The method includes determining a surface defect region of a coating on a substrate and a location of the surface defect. The method further includes selectively and locally correcting the surface defect by applying a corrective coating region to the surface defect region based on the location of the surface defect via spatial atomic layer deposition (SALD) using an SALD reactor.

### TECHNICAL FIELD

The present disclosure relates to a localized surface coating defect process, and in certain embodiments, using a spatial atomic layer deposition (SALD) for localized surface coating defect patching.

### BACKGROUND

Substrates may be coated to produce desired surface properties of the substrates. Non-limiting examples of such surface properties may include corrosion resistance, electronic conductivity, ionic conductivity, insulation, electronic surface passivation, anti-icing, anti-bio fouling, self-cleaning and super-hydrophobicity. Coated substrates may be used in many applications and industries. Non-limiting examples of applications and industries for coated substrates include automotive, construction, and home appliances. One specific application in the automotive industry is coatings of metals used in components of fuel cells, including bipolar plates (BPP). In many applications, a complete, conformal and defect-free coating is desired as a relatively small amount of coating defect may cause a failure of the coating for its intended purpose.

### SUMMARY

According to one embodiment, a method of producing a coating is disclosed. The method includes determining a surface defect region of a coating on a substrate and a location of the surface defect. The method further includes selectively and locally correcting the surface defect by applying a corrective coating region to the surface defect region based on the location of the surface defect via spatial atomic layer deposition (SALD) using an SALD reactor.

According to another embodiment, a method of producing a coating is disclosed. The method includes determining a surface defect region of a coating on a substrate moving in a longitudinal direction and a location of the surface defect. The method further includes selectively and locally correcting the surface defect by applying a corrective coating region to the surface defect region based on the location of the surface defect via spatial atomic layer deposition (SALD) using an SALD reactor while the moving substrate is moving in the longitudinal direction.

According to yet another embodiment, a method of producing a coating on a substrate is disclosed. The method includes determining a surface defect region of a coating of a first material on a substrate moving in a longitudinal direction and a location of the surface defect. The method further includes selectively and locally correcting the surface defect by applying a corrective coating of a second material to the surface defect region based on the location of the surface defect via spatial atomic layer deposition (SALD)using an SALD reactor while the moving substrate is moving in the longitudinal direction.

### BRIEF DESCRIPTION OF THE DRAWINGS

FIG. 1 is a schematic view of an inline coating system according to an embodiment.

FIG. 2 is a schematic, top view of a coated substrate according to an embodiment.

FIG. 3 is a cross section view of a defect region taken along line 3-3 of FIG. 2.

FIG. 4 is a schematic, perspective view of an SALD system as a component of the inline coating system shown in FIG. 1.

FIG. 5 is a cross section view of reactant chamber 102 of the SALD system shown in FIG. 4.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: percent, “parts of,” and ratio values are by weight; the term “polymer” includes “oligomer,” “copolymer,” “terpolymer,” and the like; the description of a group or class of materials as suitable or preferred for a given purpose in connection with the invention implies that mixtures of any two or more of the members of the group or class are equally suitable or preferred; molecular weights provided for any polymers refers to number average molecular weight; description of constituents in chemical terms refers to the constituents at the time of addition to any combination specified in the description, and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

This invention is not limited to the specific embodiments and methods described below, as specific components and/or conditions may, of course, vary. Furthermore, the terminology used herein is used only for the purpose of describing particular embodiments of the present invention and is not intended to be limiting in any way.

As used in the specification and the appended claims, the singular form “a,” “an,” and “the” comprise plural referents unless the context clearly indicates otherwise. For example, reference to a component in the singular is intended to comprise a plurality of components.

The term “substantially” may be used herein to describe disclosed or claimed embodiments. The term “substantially” may modify a value or relative characteristic disclosed or claimed in the present disclosure. In such instances, “substantially” may signify that the value or relative characteristic it modifies is within ±0%, 0.1%, 0.5%, 1%, 2%, 3%, 4%, 5% or 10% of the value or relative characteristic.

Substrate surface coating processes may be separated into two main categories based on cost and quality. The first category includes relatively lower cost, higher throughput, semi-conformal coatings. These coatings may be deposited using a solution process or a fast vapor deposition process. Non-limiting examples of solution processes include spin-coating and roll-to-roll inkjet coating. Non-limiting examples of fast vapor deposition processes include thermal evaporation and sputtering. The second category includes relatively higher cost, slower throughput, ultra-conformal thin-film coatings deposited by single atomic layers. A non-limiting example of such a process is atomic layer deposition (ALD).

While a second category coating may be utilized for many applications, the high cost associated with the relatively slow throughput of a second category process has stunted the widespread adoption of such processes. For instance, the slow throughput of an ALD process typically makes such a process less prevalent in industries outside of relatively high-value products, such as semiconductor chips. The deposition rate of an ALD process may be one of the following values or in a range between any two of the following values: 0.8, 0.9, 1.0, 1.1 and 1.2 nm/min. In emerging applications, such as fuel cell bipolar plates corrosion-resistant coatings, applying an ultra-conformal corrosion-resistant coating using an ALD process may not be viable from an economic process.

Another method has been proposed that shares certain traits of both first category and second category coatings. Spatial atomic layer deposition (SALD) is a method that can deposit ALD-quality film at a higher throughput than conventional ALD. The deposition rate of an SALD process may be one of the following values or in a range between any two of the following values: 10, 15, 20, 25, 30 and 35 nm/min. Moreover, unlike conventional ALD where the deposition chamber needs to be vacuumed and vented during each atomic layer deposition step, SALD may be performed at an atmospheric environment, facilitated by the usage of gas bearing separators. This effectively removes the lengthy vacuum-vent cycle of ALD, thereby enabling a high process throughput.

The present disclosure provides a synergistic combination of a first category coating process, such as spin-coating and roll-to-roll inkjet coating, in-line with a hybrid coating process, such as SALD, to correct surface defects imparted by the first category coating process in a spatially controlled manner. This combined process includes one or more benefits of relatively fast throughput and/or delivering a conformal, consistent, defect free coating.

“Inline” may be used to refer to a process in which two or more processes or process steps are conducted as part of a continuous process. “Inline” may refer to carrying out a first process or process step followed by carrying out a second process or process step within a relatively short period of time of the first process or process step.

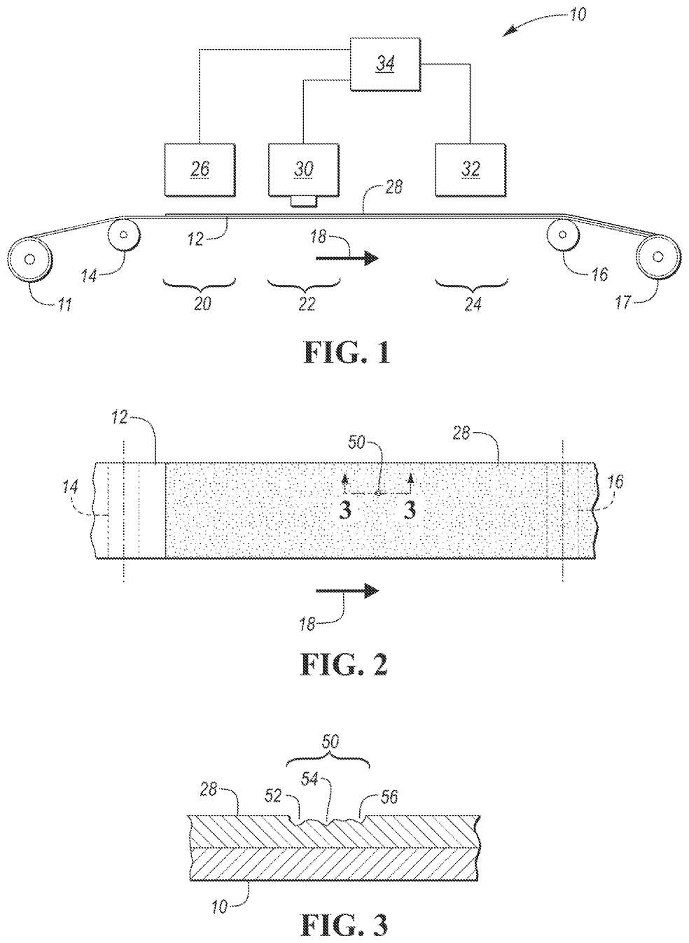

FIG. 1 is a schematic view of inline coating system 10 according to an embodiment. Substrate 12 is loaded onto first conveying roller 14. Substrate 12 may be a metal material used for the manufacture of fuel cell flow field plates, such as bipolar plates (BPP). Non-limiting examples of metal materials include stainless steel, aluminum-based alloys, titanium-based alloys, and combinations thereof. The thickness of metal material used for the manufacture of fuel cell flow field plates may be any of the following values or in a range of any two of the following values: 1.5, 1.6, 1.7, 1.8, 1.9, 2.0, 2.1, 2.2, 2.3., 2.4, and 2.5 mm. Substrate 12 may also be formed of a graphite-based material. Inline coating system 10 may be applied to a variety of substrate materials, including glass, semiconductors and polymers, in addition to metal materials and graphite-based materials.

As shown in FIG. 1, substrate 12 is horizontally conveyed using a roll-to-roll process. In other embodiments, substrate 12 may be conveyed vertically or at an angle between horizontal and vertical, relative to the ground supporting inline coating system 10. Substrate 12 may be mechanically unwound from unwinding roller 11 and horizontally conveyed in longitudinal direction 18 by first and second conveying rollers 14 and 16. Substrate 12 is wound onto winding roller 17 downstream from second conveying roller 16. The conveying rate of inline coating system 10 may be one of the following values or in a range of any two of the following values: 0.1, 0.5, 1, 2, 3, 4, 5, 6, 7, 8, 9, and 10 meters/min. The span between first and second conveying rollers 14 and 16 may be one of the following values or in a range of any two of the following values: 0.5, 1, 1.5 and 2 meters. The span between first and second conveying rollers 14 and 16 may be divided into several zones. These zones may include primary coating zone 20, detection zone 22, which is downstream from primary coating zone 20, and secondary coating zone 24, which is downstream from primary coating zone 20 and secondary coating zone 24.

In one embodiment, primary coating zone 20 includes laser printing system 26 situated above substrate 12. Laser printing system 26 is configured to apply coating 28 to substrate 12 at a thickness or range of thicknesses identified herein. Non-limiting examples of materials for coating 28 include oxides, such as binary and ternary oxides. Binary oxides may have the general formula of AₓO_{y}, where A is a metal. The composition ratio between x and y may be different or the same. Non-limiting examples of binary oxides include MgO, Al₂O₃, TiO₂, ZrO₂, ZnO, SnO₂, Cr₂O₃, MoO₃, MoO₂, NbO, TiO, CrO₂, RuO₂, CuO, NiO, MnO₂, SiO₂, and Fe₂O₃. The coating material may be a ternary oxide of ABOX form, where the A is a metal from a category (1) metal oxide and B is a metal from a category (2) metal oxide. The composition ratio between A and B may be different (e.g., A_{0.1}B_{0.9}Oₓ, A_{0.2}B_{0.8}Oₓ, A_{0.3}B_{0.7}Oₓ, A_{0.8}B_{0.2}Oₓ, A_{0.9}B_{0.1}Oₓ, etc.) or the same.

The thickness of coating 12 may be any of the following values or in the range of any two of the following values: 0.1, 0.2, 0.3, 0.4, 0.5, 0.6, 0.7 and 0.8 μm. Laser printing system 26 may be configured to coat the entire width of substrate 12 or less than the entire the entire width of substrate 12 (e.g., 90%, 80%, 50% or 25%). The width of substrate 12 may be any of the following values or in the range of any two of the following values: 0.25, 0.5, 0.75, 1, 1.5, and 2 meters. The deposition rate of laser printing system 26 may be a function of the conveying rate of substrate 12 by first and second conveying rollers 14 and 16 of inline coating system 10. The conveying rate of inline coating system 10 may be one of the following values or in a range of any two of the following values: 0.1, 0.5, 1, 2, 3, 4, 5, 6, 7, 8, 9, and 10 m/min.

Laser printing system 26 or other substrate coating system may impart coating defects on the surface and within the bulk of coating 28. The coating defect may be a defect region in which there is a deviation between the mean thickness of coating 28 and the defect region. The defect region may include one or more protrusion on the surface of coating 28 in which the protrusions have more coating thickness than the mean coating thickness. The defect region may include one or more pockets on the surface of coating 28 in which the one or more pockets do not include coating material, and therefore, the thickness of the pockets is less than the mean coating thickness. In certain embodiments, a defect region may include one or more protrusions and one or more pockets. The average thickness deviation of the one or more pockets and/or one or more protrusions may be any of the following values or in the range of any two of the following values: 10, 20, 30, 40, 50, 60, 70, 80, 90 and 100 nm. The area along the surface of coating 28 of the one or more pockets and/or one or more protrusions may be any of the following values or in the range of any two of the following values: 50, 60, 70, 80, 90, 100, 110, 120, 130, 140 and 150 nm. The defect region may include one or more a plurality of pockets and/or a plurality of protrusions. The surface area of the defect region may be any of the following values or in the range of any two of the following values: 0.01, 0.05, 0.1, 0.15 and 0.2 μm.

FIG. 2 depicts a top view of substrate 10 and coating 28 where coating 28 includes defect region 50. FIG. 3 depicts a cross section view of substrate 12 and coating 28 where coating 28 includes first, second and third defects 52, 54 and 56 within defect region 50. As shown in FIG. 3, there are a number of defects within defect region 50. Alternatively, a single defect may be present within a defect region of coating 28. First, second and third defects 52, 54 and 56 extend inward from the surface of coating 28 toward substrate 12, although it is possible for defects to extend outwardly from the surface of coating 28 away from substrate 12.

Moving back to FIG. 1, detection zone 22 includes coating thickness measurement system 30. Coating thickness measurement system 30 is configured to detect coating defect regions, such as defect region 50, in the surface of coating 28. Coating thickness measurement system 30 is inline with laser printing system 26. Coating thickness measurement system 30 is also inline with SALD system 32, which is described in more detail below. Laser printing system 26, coating thickness measurement system 30 and SALD system 32 are inline with each other because first and second conveying rollers 14 and 16 provide substrate 12 such that it moves in a longitudinal direction for each of systems 26, 30 and 32 to perform the functions associated with each of these system in succession based on the conveying rate of first and second conveying rollers 14 and 16. In connection with controller 34, coating thickness measurement system 30 may use a film characterization method to detect a defect region on the surface of coating 28, and a location of the defect region. The film characterization method can be used to create a thickness topology of at least a region or the entirety of coating 28. The thickness topology can be used to determine a mean thickness of coating 28 and the location of defect regions on the surface of coating 28. The film characterization method can detect the location of a defect region within a tolerance of any of the following or in a range of any two of the following: ±10, 20, 30, 40, 50, 60, 70, 80, 90 and 100 nm.

Non-limiting examples of film characterization methods that can be utilized by coating defect identification system 30 in conjunction with controller 34 include a laser thickness calibration method, an infrared thermography method and an X-ray fluorescence (“XRF”) method.

In an implementation of one laser thickness calibration method, coating thickness measurement system 30 includes a light source configured to radiate a laser light onto a region of coating 28, and a light detector configured to obtain optical interference data generated by the region of coating 28 by the laser light. Coating thickness measurement system 30 is configured to transmit the optical interference data to controller 34. Controller 34 is configured to calculate a thickness in different regions of coating 28 and the locations of those thicknesses based on the optical interference data.

In an implementation of one infrared thermography method, coating thickness measurement system 30 includes a heating device configured to heat a region of the surface of coating 28, and an infrared camera configured to receive infrared radiation data from the region in response to the heating. Coating thickness measurement system 30 is configured to transmit the infrared radiation data to controller 34. Controller 34 is configured to calculate a thickness in different regions of coating 28 and the locations of these thicknesses based on the infrared radiation data.

In an implementation of one XRF method, coating thickness measurement system 30 includes a controlled X-ray tube configured to irradiate the surface of coating 28 with high energy X-rays, and an X-ray detector configured to obtain fluorescent X-ray data released from the surface of coating 28. Coating thickness measurement system 30 is configured to transmit the fluorescent X-ray data to controller 34. Controller 34 is configured to calculate a thickness in different regions of coating 28 and the locations of these thicknesses based on the fluorescent X-ray data.

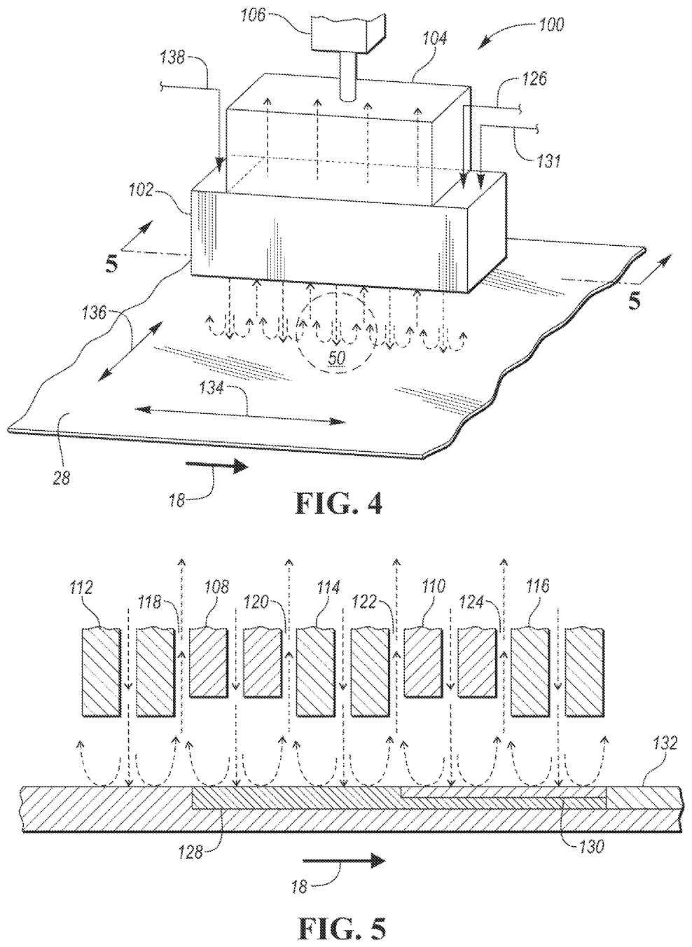

Secondary coating zone 24 includes SALD system 32. SALD system 32 is configured to patch or fill coating defects in the surface of coating 28. FIG. 4 is a perspective, schematic view of SALD reactor 100 situated above the surface of coating 28. SALD reactor is rectangularly shaped, with the longer side extending in the longitudinal direction of inline coating system 10 and the shorter side extending in the lateral direction (e.g., transverse to the longitudinal direction) of inline coating system 10, although the dimensions of the rectangular sides may be swapped so that the longer side extends in the lateral direction and the shorter side extends in the longitudinal direction.

Reactor 100 includes reactant chamber 102, exhaust manifold 104 and vacuum pump 106. FIG. 6 is a cross section view of reactant chamber 102 of SALD reactor 100. Reactant chamber 102 includes precursor nozzle 108, oxidant nozzle 110, first gas bearing nozzle 112, second gas bearing nozzle 114, and third gas bearing nozzle 116. Precursor nozzle 108 is situated between first and second gas bearing nozzles 112 and 114. Oxidant nozzle 110 is situated between second and third gas bearing nozzles 114 and 116. Reactant chamber 102 also includes first, second, third and fourth exhaust passages 118, 120, 122 and 124.

A gaseous precursor material is fed into reactant chamber 102 through gaseous precursor material inlet 126 and is directed into and through precursor nozzle 108. The precursor material may be a metal-based precursor material. The metal in the metal-based precursor material may be the same as the metal in a binary oxide coating material or the same as one of the metals in a ternary oxide coating material. In another embodiment, the metal in the metal-based precursor material may be different than the metal in the binary oxide coating material or different than both of the metals in a ternary oxide coating material. In one example, the coating material is an aluminum-based coating material, such as Al₂O₃, and the precursor material is an aluminum-based precursor, such as trimethyl aluminum (“TMA”). The precursor material exits reactant chamber 102 through precursor nozzle 108 and onto coating 28 to form precursor layer 128. As shown in FIG. 5, SALD reactor 100 is moving in longitudinal direction 18 at a speed greater than the conveying speed of first and second conveying rollers 14 and 16, such that SALD reactor deposits precursor layer 128 onto coating 28 in longitudinal direction 18. Excess gaseous precursor material moves away from coating 28 as depicted by curved arrow below precursor nozzle 108. This excess gaseous material exits reactant chamber 102 through first and second exhaust passages 118 and 120.

A gaseous oxidant material is fed into reactant chamber 102 through gaseous oxidant material inlet 131 and is directed into and through oxidant nozzle 110. The oxidant material may be H₂O, O₂, O₃ or other oxidant based on the reaction chemistry with the precursor material. The oxidant material exits reactant chamber 102 through oxidant nozzle 110 and onto coating 28 to form oxidant layer 130. As shown in FIG. 5, SALD reactor 100 is moving in longitudinal direction 18 at a speed greater than the conveying speed of first and second conveying rollers 14 and 16, such that SALD reactor deposits oxidation layer 128 onto coating 28 in longitudinal direction 18. Excess gaseous oxidant material moves away from coating 28 as depicted by curved arrow below oxidant nozzle 110. This excess gaseous material exits reactant chamber 102 through third and fourth exhaust passages 122 and 124.

As precursor layer 128 and oxidant layer 130 commingle, a reaction takes place that forms an oxide material. If the precursor material is an aluminum-based precursor material, the reaction would yield Al₂O₃, which would be formed as a layer on coating 28. Such a layer may be layer 132 shown in FIG. 5.

First, second and third gas bearing nozzles 112, 114 and 116 are configured to stream inert gases (entering reactant chamber through inert gas inlet 138) between precursor and oxidant reactants so that they do not come into contact with each outside of an intended reaction zone. Non-limiting examples of inert gases include nitrogen, neon, xenon, and argon. The streams of inert gases can act as a gas bearing to reduce friction between SALD reactor 100 and coating 28. The inert gas streams are also configured to carry excess reactants (e.g., precursor and oxidant) away from the surface of coating 28 and through exhaust passages 118, 120, 122 and 124. Exhaust passages 118, 120, 122 and 124 are connected to exhaust manifold 104, which is connected to vacuum pump 106. Vacuum pump 106 is configured to put exhaust passages 118, 120, 122 and 124 into a vacuum state. Accordingly, gas streams exiting exhaust passages 118, 120, 122 and 124 are discharged at a second pressure less than an atmospheric pressure from exhaust passages 118, 120, 122 and 124. During the gas stream discharge operation, the SALD reactor 100 and substrate 12 may be in a load lock chamber to maintain the substrate 12 in a vacuum state. The gas stream discharge operation limits or eliminates the leakage of precursor gases.

Reactant chamber 102 includes bottom surface 132. Bottom surface 132 is rectangularly shaped and nozzles 108 through 116 extend along the shorter side of reactant chamber 132 such that the gaseous streams created therefrom are in sheets extending in the shorter side direction of reactant chamber 102. The area of bottom surface 132 may be greater than the defect region but less than region of coating 28 being samples by coating thickness measurement system 30. Reactant chamber 102 may be used to lay down corrective layers of coating material in the defect region and around the defect region to ensure that the entire defect region is treated with the corrective coating layer. The percentage of overspray area of corrective coating layer in addition to the defect region area may be any of the following values or in the range of any two of the following values: 1, 2, 3, 4, 5, 6, 7, 8, 9, 10, 15 or 20 percent. In certain embodiments, reactant chambers 102 can be repeated to increase the overall area for the corrective coating laid down on coating 32.

As shown by arrows 134 and 136, SALD reactor 100 is configured to translate in first and second directions relative to substrate 12 having coating 28. In one embodiment, SALD reactor 100 is attached to a carriage that is configured to translate in first and second directions, thereby translating the SALD reactor 100 in the first and second directions. In one embodiment, the first and second directions are transverse to each other.

Controller 34 is configured to receive coating thickness data from coating thickness measurement system 30 and to determine thickness of coating 32 by location in each sample region of coating 32 based on the coating thickness data. Based on the determined thickness location data, controller 32 determines patching defect regions (e.g., defect region 50) in coating 32. Based on the determination of defect regions and locations and areas thereof, controller 34 creates instructions to be transmitted to SALD system 32 so that SALD system 32 can apply a localized SALD coating to resolve the defect regions. The deposition rate of the localized SALD coating may be any of the following or in a range of any two of the following: 10, 20, 30 or 40 nm/min. Controller 34 may be further configured to send instructions to the system (e.g., carriage motors) connected to SALD system 32 configured to translate SALD system 32. These instructions can be used to move SALD system 32 when it is in a non-operational mode while it is moving between defect regions. The instructions transmitted to SALD system 32 can be used to activate SALD system 32 when it above or in the vicinity of a defect region, and to deactivate SALD system 32 when it is finished correcting the defect(s) within the defect region.

The controller 34 may include one or more devices selected from microprocessors, micro-controllers, digital signal processors, microcomputers, central processing units, field programmable gate arrays, programmable logic devices, state machines, logic circuits, analog circuits, digital circuits, or any other devices that manipulate signals (analog or digital) based on computer-executable instructions residing in memory. The memory may include a single memory device or a number of memory devices including, but not limited to, random access memory (RAM), volatile memory, non-volatile memory, static random access memory (SRAM), dynamic random access memory (DRAM), flash memory, cache memory, or any other device capable of storing information. The non-volatile storage may include one or more persistent data storage devices such as a hard drive, optical drive, tape drive, non-volatile solid state device, cloud storage or any other device capable of persistently storing information.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A method of producing a coating, the method comprising:
determining a surface defect region of a coating on a substrate and a location of the surface defect; and
selectively and locally correcting the surface defect by applying a corrective coating region to the surface defect region based on the location of the surface defect via spatial atomic layer deposition (SALD) using an SALD reactor.

2. The method of claim 1, wherein the determining and correcting steps are carried out inline with each other.

3. The method of claim 1, wherein the corrective coating region covers the surface defect region and an overspray region adjacent to the surface defect region.

4. The method of claim 1, wherein the correcting step includes translating the SALD reactor relative to the substrate and the coating so that the SALD reactor is located above the defect region.

5. The method of claim 4, wherein the correcting step further includes activating the SALD reactor when the SALD reactor is located above the defect region.

6. The method of claim 1, wherein the determining step is carried out using a coating thickness measurement system.

7. The method of claim 6, wherein the coating thickness measurement system implements infrared thermography, visible-light optical inspection, X-ray fluorescence, or X-ray diffraction.

8. A method of producing a coating, the method comprising:
determining a surface defect region of a coating on a substrate moving in a longitudinal direction and a location of the surface defect; and
selectively and locally correcting the surface defect by applying a corrective coating region to the surface defect region based on the location of the surface defect via spatial atomic layer deposition (SALD) using an SALD reactor while the moving substrate is moving in the longitudinal direction.

9. The method of claim 8, wherein the corrective coating region covers the surface defect region and an overspray region adjacent to the surface defect region.

10. The method of claim 8, wherein the selectively and locally correcting step is carried out in a load lock chamber.

11. The method of claim 8, wherein the determining and correcting steps are carried out inline with each other.

12. The method of claim 8, wherein the correcting step includes translating the SALD reactor relative to the substrate and the coating so that the SALD reactor is located above the defect region.

13. The method of claim 8, wherein the correcting step further includes activating the SALD reactor when the SALD reactor is located above the defect region.

14. The method of claim 8, wherein determining step is carried out using infrared thermography, visible-light optical inspection, X-ray fluorescence, or X-ray diffraction.

15. A method of producing a coating on a substrate, the method comprising:
determining a surface defect region of a coating of a first material on a substrate moving in a longitudinal direction and a location of the surface defect; and
selectively and locally correcting the surface defect by applying a corrective coating of a second material to the surface defect region based on the location of the surface defect via spatial atomic layer deposition (SALD) having an SALD reactor while the moving substrate is moving in the longitudinal direction.

16. The method of claim 15, wherein the second material is TiO₂, Al₂O₃, HfO₂, SiO₂, ZnO, In₂O₃, or combinations thereof.

17. The method of claim 15, wherein the determining step is carried out using infrared thermography, visible-light optical inspection, X-ray fluorescence, or X-ray diffraction.

18. The method of claim 15, wherein the selectively and locally correcting step is carried out in an atmospheric environment.

19. The method of claim 15, wherein the second material is a pure metal material.

20. The method of claim 19, wherein the pure metal material is Ta, Ti, Si, Ge, Ru, Pt, or combinations thereof.
